(19) United States
(12) Patent Application Publication
(10) Pub. No.: US 2010/0084683 A1
(43) Pub. Date: Apr. 8, 2010

(54) LIGHT EMITTING DIODE PACKAGE AND FABRICATING METHOD THEREOF

(75) Inventors: Kou-Rueh Lai, Hsinchu City (TW); Gwo-Shii Yang, Hsinchu City (TW); Kung-Chi Ho, Hsinchu County (TW); Hu-Chen Tsai, Hsinchu County (TW); Wen-Chuan Wang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NOVALITE OPTRONICS CORP., Hsinchu City (TW)

(21) Appl. No.: 12/632,737

(22) Filed: Dec. 7, 2009

Related U.S. Application Data
(63) Continuation-in-part of application No. 11/535,991, filed on Sep. 28, 2006.

(30) Foreign Application Priority Data
Feb. 23, 2006 (TW) 95106043
Dec. 8, 2008 (CN) 200810178897.1

(51) Int. Cl. H01L 33/00; H01L 21/50

(52) U.S. Cl. 257/99; 438/26; 257/100; 257/98; 257/E33.059; 257/E33.066; 257/E21.499

(57) ABSTRACT

A light emitting diode (LED) package is provided. The LED package includes a carrier, a package housing, a strength enhancement structure, an ESD protector and an LED chip. The carrier has a first surface and a second surface. The carrier includes a first electrode and a second electrode, wherein a gap is between the first electrode and the second electrode. The package housing is disposed on the carrier and has a first aperture and a second aperture. The first surface is exposed by the first aperture while the second surface is exposed by the second aperture. The strength enhancement structure is disposed at the gap. The ESD protector is disposed on the carrier and located within the second aperture. The LED chip is disposed on the carrier and located within the first aperture, wherein the ESD protector and the LED chip is electrically connected to the carrier.

### CROSS-REFERENCE TO RELATED APPLICATION

This application is a continuation-in-part of and claims priority benefit of an application Ser. No. 11/535,991, filed on Sep. 28, 2006, which claims the priority benefit of Taiwan patent application serial no. 95106043, filed on Feb. 23, 2006. This application also claims he priority benefit of P.R.C. patent application serial no. 200810178897.1, filed on Dec. 8, 2009. The entirety of each of the above-mentioned patent application is hereby incorporated by reference herein and made a part of specification.

### BACKGROUND OF THE INVENTION

1. Field of the Invention

The present invention relates to a package and a fabricating method thereof. More particular, the present invention relates to a light emitting diode (LED) package with and a fabricating method thereof.

2. Description of Related Art

Due to advantages of long lifetime, small volume, great resistance to vibration, low heat emission, and low power consumption, LEDs have been extensively applied in various home appliances and instruments as indicators or light sources. With recent development towards multicolor and high illumination, the applications of LEDs are extended to large-sized outdoor billboards, traffic lights, etc. In the future, LEDs may become the power-saving and environment-protecting light sources in replacement of tungsten filament lamps and mercury vapor lamps. FIG. 1A is a schematically top view of a conventional LED package. FIG. 1B is a schematic cross-sectional view illustrating the LED package shown in FIG. 1A taken along line A-A′. Referring to FIG. 1A and FIG. 1B, a conventional LED package 100 includes a leadframe 110, a package housing 120, an LED chip 130, an ESD protector 140, a plurality of conductive wires 150, and an encapsulant 160. The leadframe 110 has a first surface 111 and a second surface 112. Furthermore, the leadframe 110 has a gap W. The package housing 120 is formed over the leadframe 110 so as to form a chip accommodating space S on the first surface 111. The LED chip 130 is disposed on the first surface 111 of the leadframe 110 and is located within the chip accommodating space S. The ESD protector 140 is disposed on the second surface 112 of the leadframe 110. The LED chip 130 is electrically connected with the leadframe 110 via the bonding wires 150. The ESD protector 140 is electrically connected with the leadframe 110 via the bonding wires 150 also. The encapsulant 160 encapsulates the LED chip 130 and the bonding wires 150 located within the chip accommodating space S. It is noted that the package housing 120 entirely encapsulates the second surface 112 of the leadframe 110, the ESD protector 140, and the bonding wires 150 electrically connected with the ESD protector 140. Since the second surface 112 of the leadframe 110 is physically supported by the package housing 120, the leadframe 110 has sufficient strength to carry the LED chip 130.

However, since the bonding wires 150 electrically connected with the ESD protector 140 are encapsulated by the package housing 120, the bonding wires 150 electrically connected with the ESD protector 140 are damaged easily during fabrication. Specifically, the bonding wires 150 may be damaged by liquid molding compound when a mold injection process is performed to form the package housing 120. Accordingly, yield rate of the LED package 100 is reduced. In addition, since the second surface 112 of the leadframe 110 is encapsulated by the package housing 120, amount of the material required for fabricating the package housing 120 is significant.

FIG. 1C is a schematically top view of another conventional LED package. Referring to FIG. 1B and FIG. 1C, the LED package 100′ shown in FIG. 1C is similar with the LED package 100 shown in FIG. 1B except that the LED package 100′ is a surface mount device fabricated by surface mount technology (SMT). The ESD protector 140 is electrically connected with the leadframe 110 via conductive bumps 142. The damaged issue of the bonding wires 150 can be solved in the LED package 100′. However, the fabrication cost increases significantly because the surface mount technology (SMT) is much more complex than wire bonding process.

### SUMMARY OF THE INVENTION

The present application is directed to an LED package having apertures for accommodating devices. The LED package of the present application is capable of avoiding damage of bonding wires such that the yield rate of the LED package is increased and the fabrication cost is reduced.

The present application is directed to a method of fabricating an LED package, which has simpler fabricating processes and is advantage in reduced fabrication cost.

The present invention provides an LED package including a carrier, a package housing, a strength enhancement structure, an ESD protector and an LED chip. The carrier has a first surface and a second surface opposite to the first surface. The carrier includes a first electrode and a second electrode, wherein a gap is between the first electrode and the second electrode. The package housing is disposed on the carrier and has a first aperture and a second aperture, wherein the first surface is exposed by the first aperture while the second surface is exposed by the second aperture. The strength enhancement structure is disposed on the carrier and fills at least parts of the gap. The ESD protector is disposed on the carrier and located within the second aperture, wherein the ESD protector is electrically connected to the carrier. The LED chip is disposed on the carrier and located within the first aperture, wherein the LED chip is electrically connected to the carrier.

In an embodiment of the present application, the strength enhancement structure is disposed on the second surface of the carrier.

In an embodiment of the present application, the strength enhancement structure and the package housing are formed integrally.

In an embodiment of the present application, the thickness of the strength enhancement structure is greater than or equal to 0.25 micrometer.

In an embodiment of the present application, the LED package further includes at least one bonding wire, wherein the ESD protector is electrically connected with the carrier via the bonding wire.

In an embodiment of the present application, the LED package further includes a plurality of bumps, wherein the ESD protector is electrically connected with the carrier via the bumps.

In an embodiment of the present application, the ESD protector includes a zener diode chip, a red light LED chip, a SMD type zener diode package, a SMD type red light LED package, a capacitor, a variable resistor or a surge absorber.

In an embodiment of the present application, the carrier is a leadframe.

In an embodiment of the present application, the LED package further includes at least one bonding wire, wherein the LED chip is electrically connected with the carrier via the bonding wire.

In an embodiment of the present application, the LED package further includes a plurality of bumps, wherein the LED chip is electrically connected with the carrier via the bumps.

In an embodiment of the present application, the LED package further includes an encapsulant, wherein the encapsulant encapsulates the LED chip and parts of the carrier exposed by the first aperture.

In an embodiment of the present application, the LED package further includes a phosphor doped encapsulant, wherein the phosphor doped encapsulant encapsulates the LED chip and parts of the carrier exposed by the first aperture.

In an embodiment of the present application, the material of the package housing includes plastic, metal, or metal oxide.

The present application is also directed to a method for fabricating a light emitting diode package. First, a carrier having a first surface and a second surface opposite to the first surface is provided. The carrier includes a first electrode and a second electrode, wherein a gap is between the first electrode and the second electrode. A package housing bonded with the carrier is then formed, wherein the package housing has a first aperture and a second aperture, the first surface is exposed by the first aperture while the second surface is exposed by the second aperture. Afterward, a strength enhancement structure is formed on the carrier to fill at least parts of the gap. Next, an ESD protector is disposed on the carrier exposed by the second aperture, wherein the ESD protector is electrically connected to the carrier. Then, an LED chip is disposed on the carrier exposed by the first aperture, wherein the LED chip is electrically connected to the carrier.

In an embodiment of the present application, the strength enhancement structure is formed on the second surface of the carrier.

In an embodiment of the present application, the strength enhancement structure and the package housing are formed integrally.

In an embodiment of the present application, the thickness of the strength enhancement structure is greater than or equal to 0.25 micrometer.

In an embodiment of the present application, the ESD protector is disposed on and electrically connected with the carrier through surface mount technology (SMT).

In an embodiment of the present application, the ESD protector is disposed on and electrically connected with the carrier through flip-chip bonding technology.

In an embodiment of the present application, the ESD protector is electrically connected with the carrier through wire bonding technology.

In an embodiment of the present application, the LED chip is disposed on and electrically connected with the carrier through flip-chip bonding technology.

In an embodiment of the present application, the LED chip is electrically connected with the carrier through wire bonding technology.

In an embodiment of the present application, the LED package further includes forming an encapsulant after the LED chip and the carrier are electrically connected, wherein the encapsulant encapsulates the LED chip and parts of the carrier exposed by the first aperture.

In an embodiment of the present application, the LED package further includes forming a phosphor doped encapsulant after the LED chip and the carrier are electrically connected, wherein the phosphor doped encapsulant encapsulates the LED chip and parts of the carrier exposed by the first aperture.

In an embodiment of the present application, the method of forming the package housing bonded with the carrier includes mold injection process or cast molding process.

In the LED package of the present application, a first aperture and a second aperture are formed to improve damage issue of bonding wires. Accordingly, amount of the material required for fabricating the package housing and the fabrication cost is reduced. In addition, the yield rate of the LED package is increased enhanced, since the physical strength of the carrier is enhanced by the strength enhancement structure.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematically top view of a conventional LED package.

FIG. 1B is a schematic cross-sectional view illustrating the LED package shown in FIG. 1A taken along line A-A′.

FIG. 1C is a schematically top view of another conventional LED package.

FIG. 2A is a schematic view of an LED package according to an embodiment of the present invention.

FIG. 2B is a schematic cross-sectional view illustrating the LED package shown in FIG. 2A taken along line B-B′.

FIG. 3A is a schematic view of an LED package according to another embodiment of the present invention.

FIG. 3B is a schematic cross-sectional view illustrating the LED package shown in FIG. 3A taken along line C-C′.

FIG. 3C is a diagram illustrating that the strength enhancement structure and the package housing are formed at the same time.

FIG. 4A is a schematic view of an LED package according to still another embodiment of the present invention.

FIG. 4B is a schematic cross-sectional view illustrating the LED package shown in FIG. 4A taken along line D-D′.

FIG. 5A is a schematic view of an LED package according to yet another embodiment of the present invention.

FIG. 5B is a schematic cross-sectional view illustrating the LED package shown in FIG. 5A taken along line E-E′.

FIGS. 6A-6D are schematic cross-sectional views illustrating a process flow for fabricating a light emitting diode package according to an embodiment of the present invention.

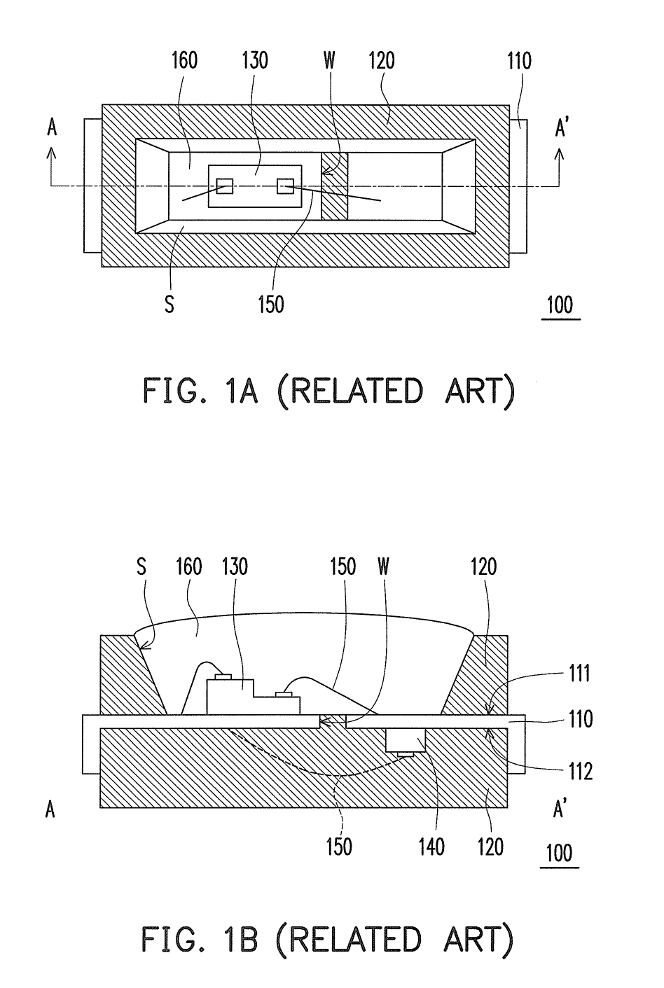

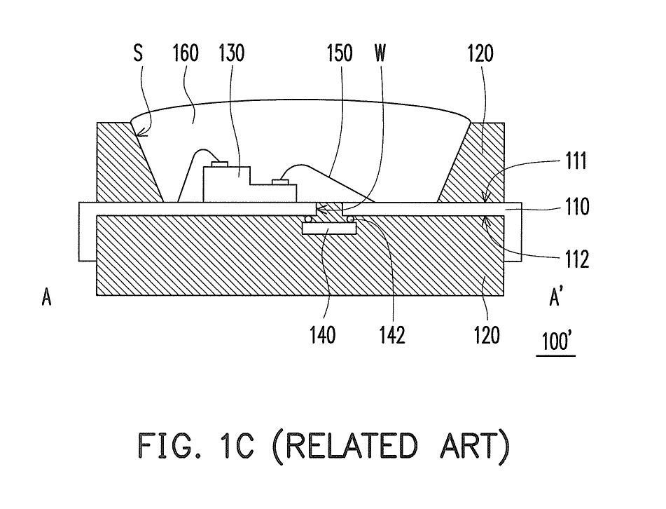

### DESCRIPTION OF EMBODIMENTS

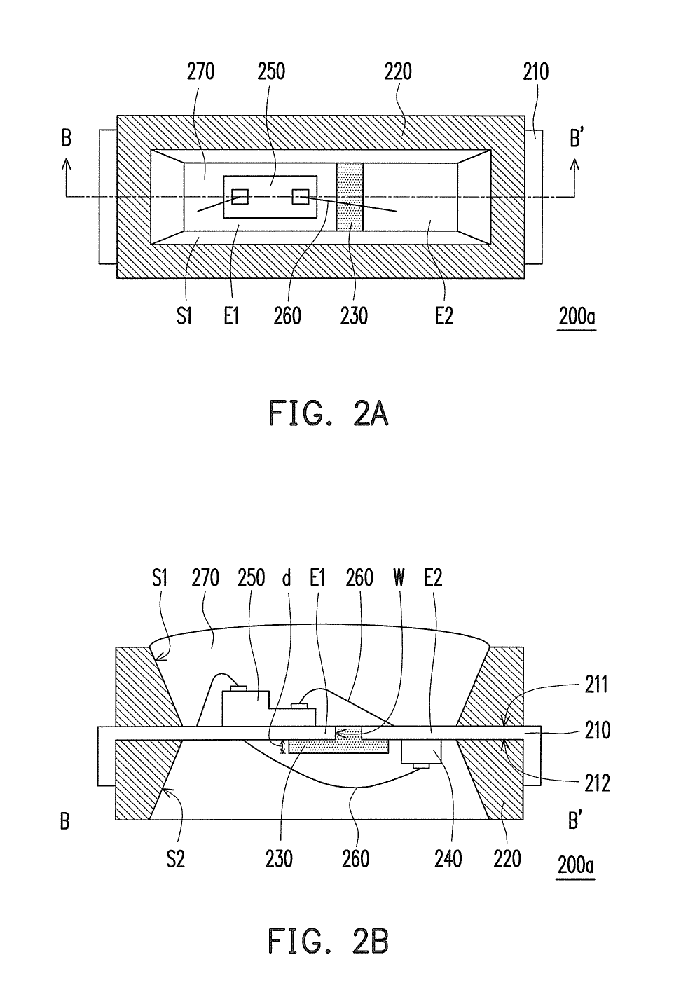

FIG. 2A is a schematic view of an LED package according to an embodiment of the present invention. FIG. 2B is a schematic cross-sectional view illustrating the LED package shown in FIG. 2A taken along line B-B′. Referring to FIG. 2A and FIG. 2B, the LED package 200a of the present embodiment includes a carrier 210, a package housing 220, a strength enhancement structure 230, an ESD protector 240, and an LED chip 250. The carrier 210 has a first surface 211 and a second surface 212 opposite to the first surface 211. The first surface 211 includes a first electrode E1 and a second electrode E2, wherein a gap W is between the first electrode E1 and the second electrode E2. The package housing 220 is disposed on the carrier 210 and has a first aperture S1 and a second aperture S2, wherein the first surface 211 is exposed by the first aperture S1 while the second surface 212 is exposed by the second aperture S2. The strength enhancement structure 230 is disposed on the carrier 210 and fills at least parts of the gap W. The ESD protector 240 is disposed on the carrier 210 and located within the second aperture S2, wherein the ESD protector 240 is electrically connected to the carrier 210. The LED chip 250 is disposed on the carrier 210 and located within the first aperture S1, wherein the LED chip 250 is electrically connected to the carrier 210.

Referring to FIG. 2A, the carrier 210 is a leadframe, for example. However, the carrier 210 of the present application is not limited to a leadframe, other suitable carriers can be used also. Additionally, the material of the package housing 220 includes plastic, metal or metal oxide, for example. The LED package 200a further includes at least one bonding wire(s) 260, wherein the ESD protector 240 is electrically connected with the carrier 210 via the bonding wire 260 while the LED chip 250 is electrically connected with the carrier 210 via the bonding wire 260.

It is noted that when the ESD protector 240 and the LED chip 250 are electrically connected with the carrier 210 via the bonding wires 260, the bonding wires 260 are not damaged during fabrication of the package housing 220 because of the first aperture S1 and the second aperture S2 defined by the package housing 220. Additionally, the first aperture S1 and the second aperture S2 may reduce amount of the material required for fabricating the package housing 220. Since parts of the gap W of the carrier 210 is filled with the strength enhancement structure 230, the overall strength of the carrier 210 is enhanced. The strength enhancement structure 230 is described in detail as following.

Referring to FIG. 2A and FIG. 2B, the strength enhancement structure 230 is disposed on the second surface 212 of the carrier 210. Since the strength enhancement structure 230 is made from opaque materials, light emitted from the LED chip 250 is not absorbed by the strength enhancement structure 230 and the illumination efficiency of the LED package 200a is enhanced accordingly. It is noted that the position of the strength enhancement structure 230 is not limited to being disposed on the second surface 212 of the carrier 210. In other words, the strength enhancement structure 230 may be disposed on the first surface 211 of the carrier 210 (not shown).

Referring to FIG. 2B, the thickness d of the strength enhancement structure 230 may be adjusted in accordance with design requirements. In a preferred embodiment, the thickness d of the strength enhancement structure 230 is not less than 0.25 micrometer. Under the condition, the strength enhancement structure 230 provides sufficient support to the carrier 210.

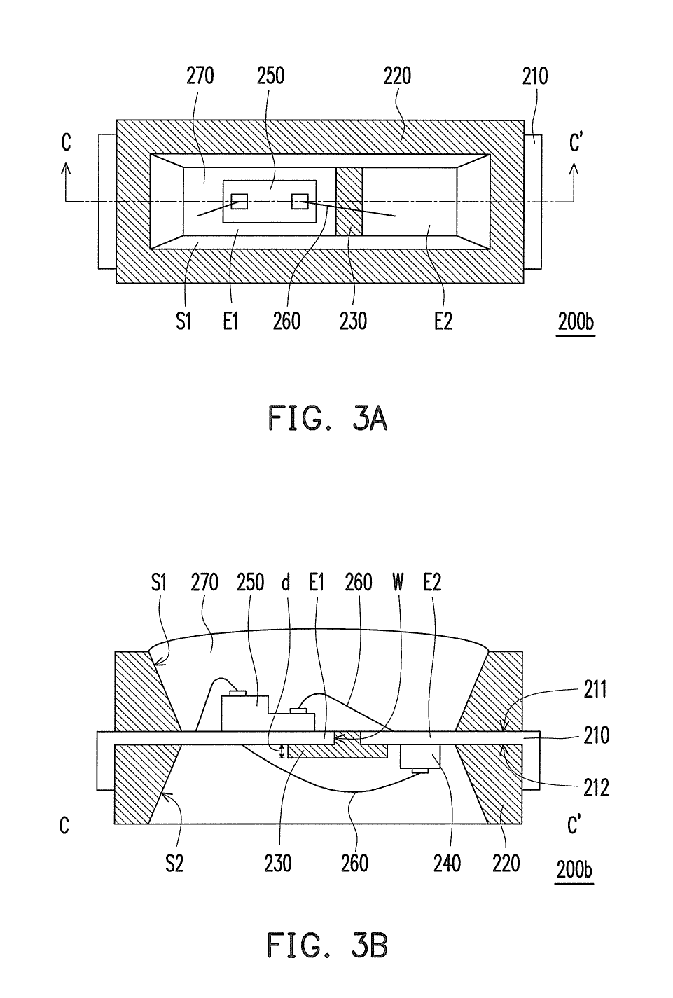

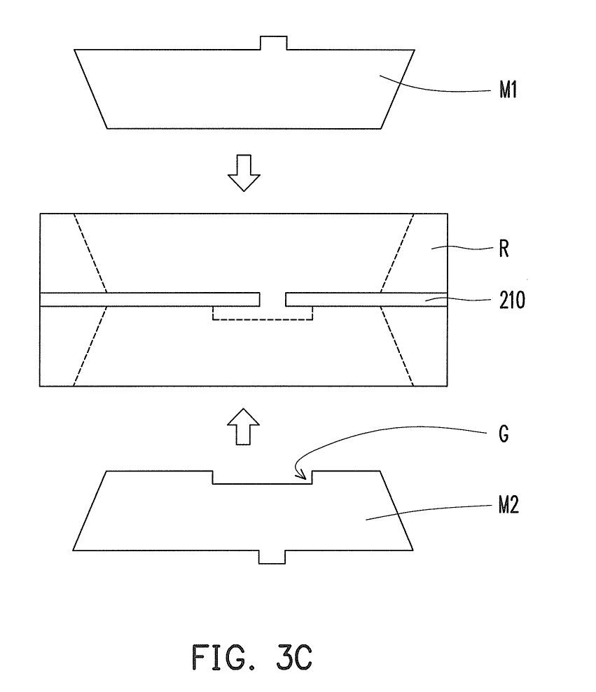

FIG. 3A is a schematic view of an LED package according to another embodiment of the present invention. FIG. 3B is a schematic cross-sectional view illustrating the LED package shown in FIG. 3A taken along line C-C′. Referring to both FIG. 3A and FIG. 3B, the LED package 200b of the present embodiment is similar to the LED package 200a. Same reference numbers in FIG. 3A and FIG. 3B represent the same elements as those in FIGS. 2A and 2B. The LED package 200b is similar to the LED package 200a except that the strength enhancement structure 230 and the package housing 200 illustrating in FIG. 3A and FIG. 3B are formed integrally while the strength enhancement structure 230 and the package housing 200 illustrating in FIG. 2A and FIG. 2B are formed by different steps respectively.

In other words, the strength enhancement structure 230 and the package housing 200 illustrating in FIG. 3A and FIG. 3B are formed simultaneously. FIG. 3C is a diagram illustrating that the strength enhancement structure and the package housing are formed at the same time. Referring to FIG. 3C, first, a plastic layer R is formed over the carrier 210. Then, a first mold M1 and a second mold M2 are provided to perform a cast molding process. The second mold M2 has a groove G corresponding to the strength enhancement structure 230. When the first mold M1 is moved upward and the second mold M2 is moved downward after the cast molding process, the package housing 220 and the strength enhancement structure 230 are formed. Due to the strength enhancement structure 230, the strength of the carrier 210 is sufficient to prevent damage resulted from the moving of the first mold M1 and the second mold M2.

Since the strength enhancement structure 230 and the package housing 220 are formed simultaneously, sufficient strength of the carrier 210 can be obtained when the first mold M1 and the second mold M2 are moving. It is noted that the strength enhancement structure 230 may be different in shape. The shape of the strength enhancement structure 230 can be determined by design of the groove G of the second mold M2. The above-mentioned embodiment is only for illustration, one ordinary skilled in the art may properly modify according to actual requirements.

Referring to FIG. 2A and FIG. 2B, the ESD protector 240 may be a zener diode chip, a red light LED chip, a SMD type zener diode package, a SMD type red light LED package, a capacitor, a variable resistor or a surge absorber.

The ESD protector 240 may be electrically connected with the carrier 210 through wire bonding technology or flip-chip bonding technology. If the ESD protector 240 is a SMD type zener diode package, a SMD type red light LED package, the ESD protector 240 may be electrically connected with the carrier 210 through solder material (not shown). If the ESD protector 240 is a variable resistor, the ESD protector 240 has function of providing high resistant protection or providing variable resistant protection. In the present embodiment, a chip-type ESD protector 240 (e.g. zener diode chip, a red light LED chip) is described for the purpose of illustration.

Referring to FIG. 2A and FIG. 2B, the LED package 200a further includes an encapsulant 270, wherein the encapsulant 270 encapsulates the LED chip 250 and parts of the carrier 210 exposed by the first aperture S1. The encapsulant 270 protects the devices encapsulated thereby from damaged by temperature and moisture. Generally, the material of the encapsulant 270 includes silicon resin or other suitable optical materials. In addition, a phosphor doped encapsulant 270 may be used. When light is emitted from the LED chip 250 of the LED package 200a, the phosphor doped in the encapsulant 270 is excited and emits secondary light with another color. For example, the LED chip 250 is a blue light LED chip while phosphor is excited by blue light emitted from the blue light LED chip and emits yellow light. White light may be obtained by mixing the blue light emitted from the blue light LED chip and the yellow light emitted from the phosphor.

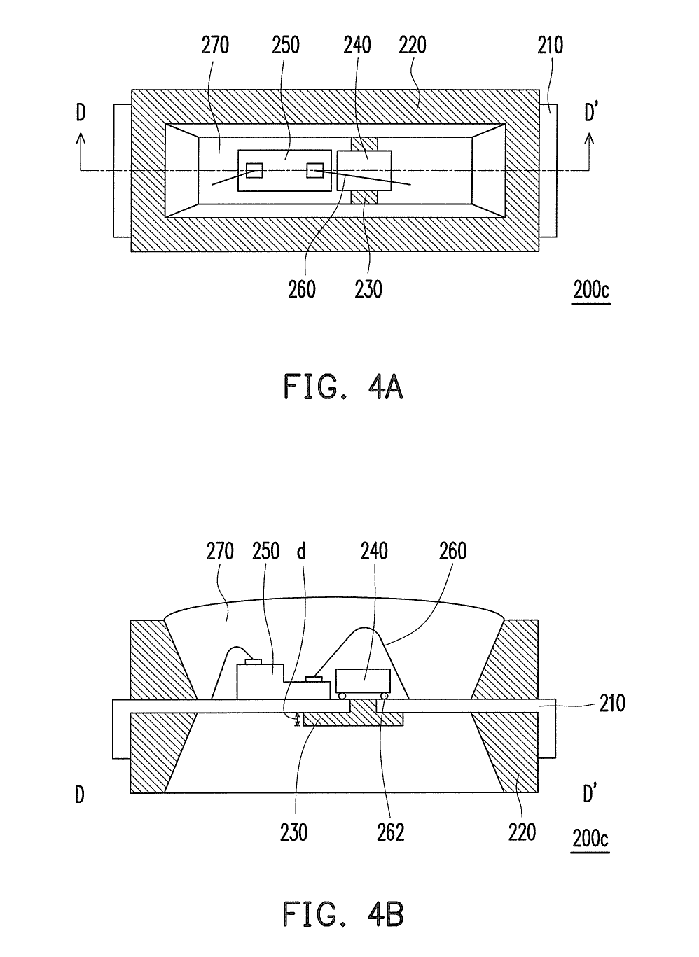

In addition to the bonding wires 260, the electrical connection between the LED chip 250, the ESD protector 240 and the carrier 210 can be carried out through bumps used in flip-chip bonding technology or solder material used in surface mount technology (SMT). FIG. 4A is a schematic view of an LED package according to still another embodiment of the present invention. FIG. 4B is a schematic cross-sectional view illustrating the LED package shown in FIG. 4A taken along line D-D′. Referring to FIG. 2A, FIG. 2B, FIG. 4A and FIG. 4B, the LED package 200c of the present embodiment is similar to the LED package 200a. Same reference numbers in FIG. 4A and FIG. 4B represent the same elements as those in FIGS. 2A and 2B. The LED package 200c is similar to the LED package 200a except that the LED package 200c further includes a plurality of bumps 262, wherein the ESD protector 240 is electrically connected with the carrier 210 via the bumps 262. As shown in FIG. 4A and FIG. 4B, the ESD protector 240 is flipped on and electrically connected with the carrier 210 through flip-chip bonding technology.

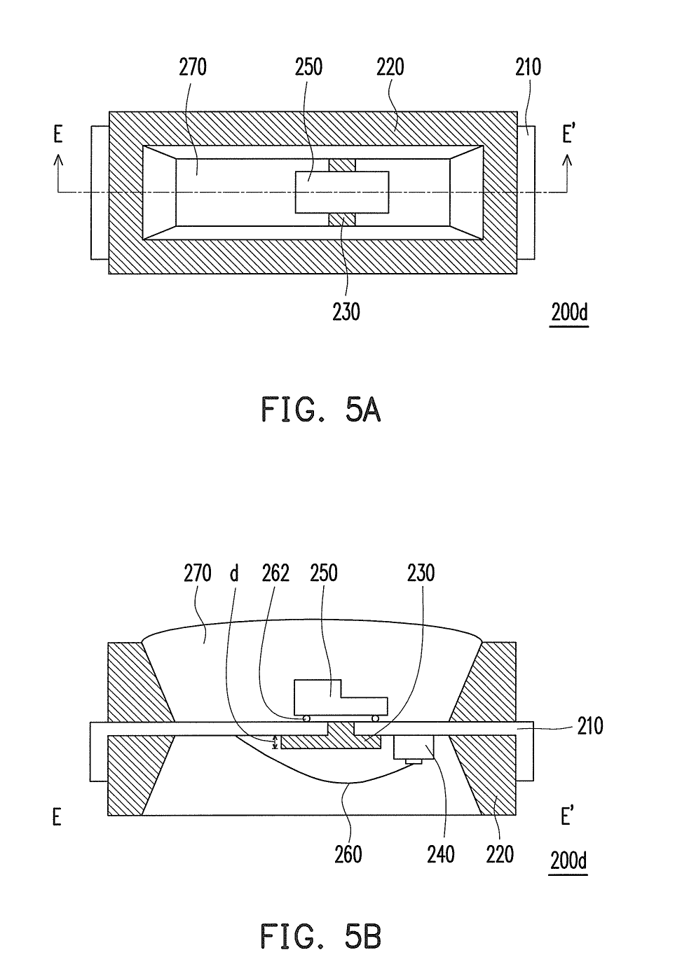

FIG. 5A is a schematic view of an LED package according to yet another embodiment of the present invention. FIG. 5B is a schematic cross-sectional view illustrating the LED package shown in FIG. 5A taken along line E-E′. Referring to FIG. 2A, FIG. 2B, FIG. 5A and FIG. 5B, the LED package 200d of the present embodiment is similar to the LED package 200a. Same reference numbers in FIG. 5A and FIG. 5B represent the same elements as those in FIGS. 2A and 2B. The LED package 200d is similar to the LED package 200a except that the LED package 200c further includes a plurality of bumps 262, wherein the ESD protector 250 is electrically connected with the carrier 210 via the bumps 262. As shown in FIG. 5A and FIG. 5B, the LED chip 250 is flipped on and electrically connected with the carrier 210 through flip-chip bonding technology. The above-mentioned electrical connection is described for illustration only, and the present application is not limited thereto. One ordinary skilled in the art may modify the electrical connection between the ESD protector 240, the LED chip 250 and the carrier 210 in accordance with design requirements.

In the above-mentioned LED packages 200a-200d, amount of the material required for fabricating the package housing 220 and the fabrication cost is reduced due to the first aperture S1 and the second aperture S2. In addition, the damaged issue of the bonding wires 260 can be avoided by the first aperture S1 and the second aperture S2 such that yield rate of wire bonding process can be effectively enhanced. It is noted that deformation of the carrier 210 resulted from bonding stress is not occurred easily when the ESD protector 240 and the LED chip 250 are bonded thereto, since the strength enhancement structure 230 provides the carrier 210 sufficient strength.

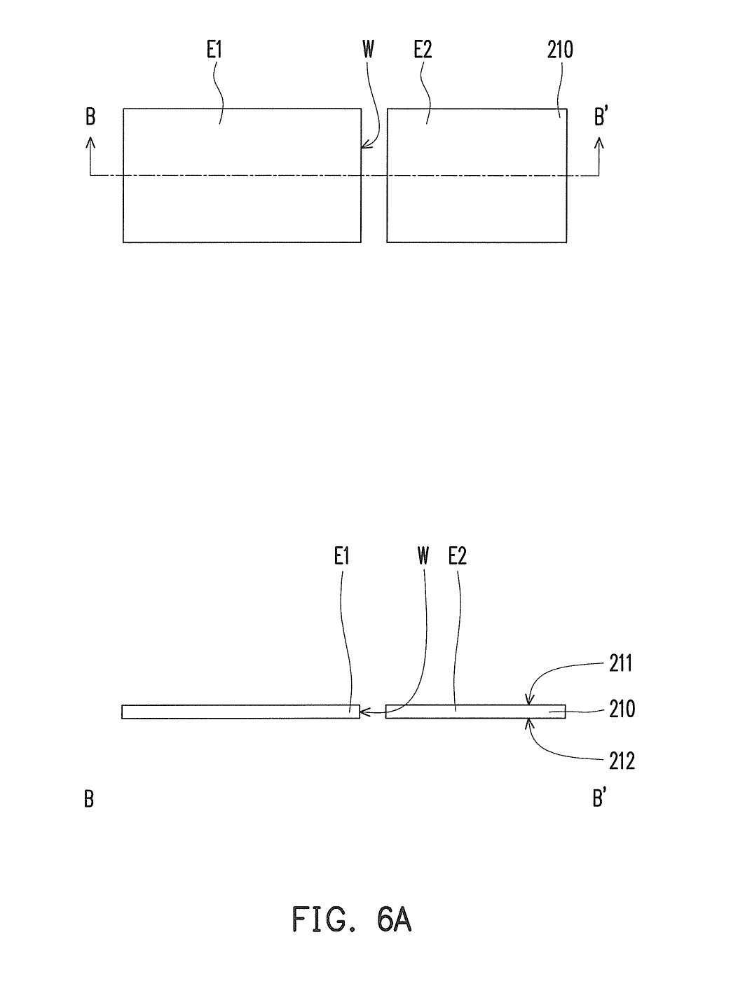

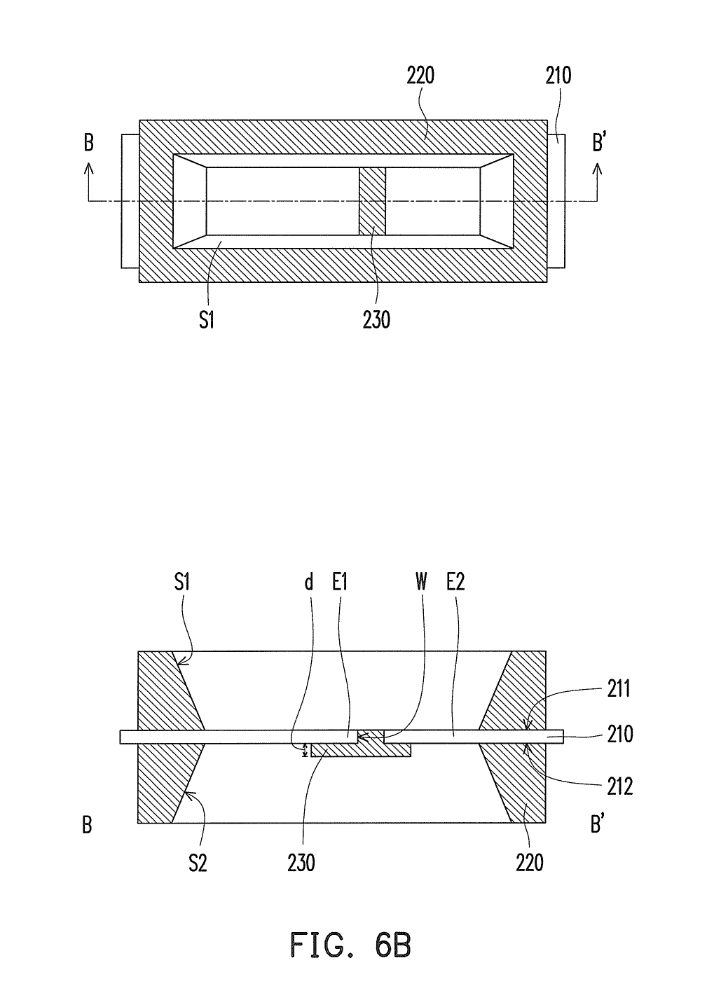

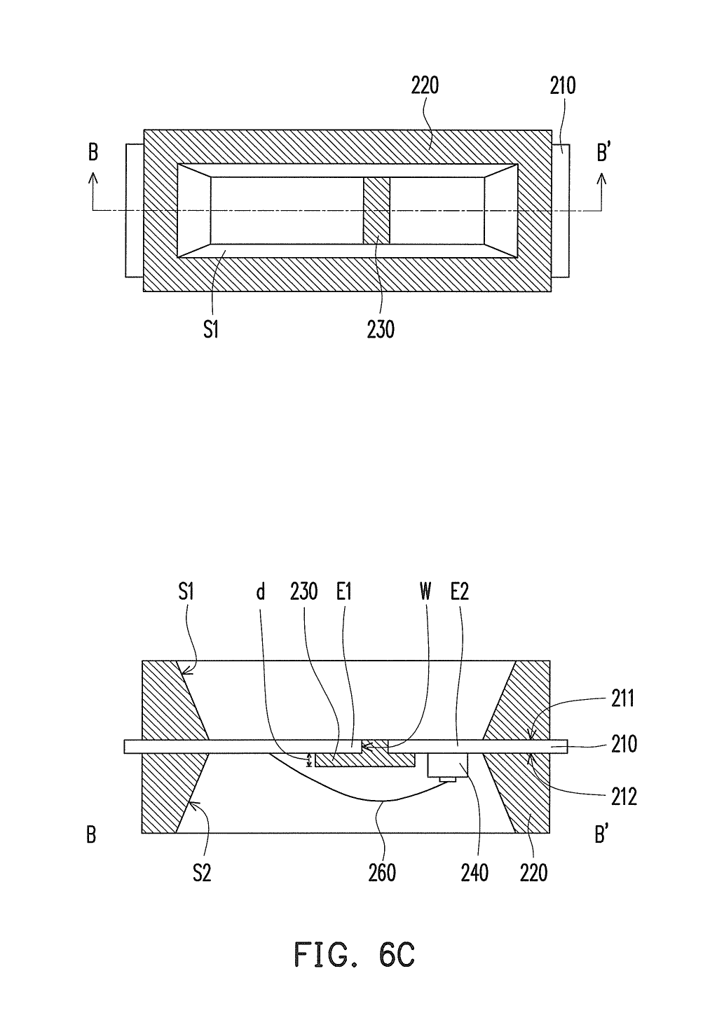

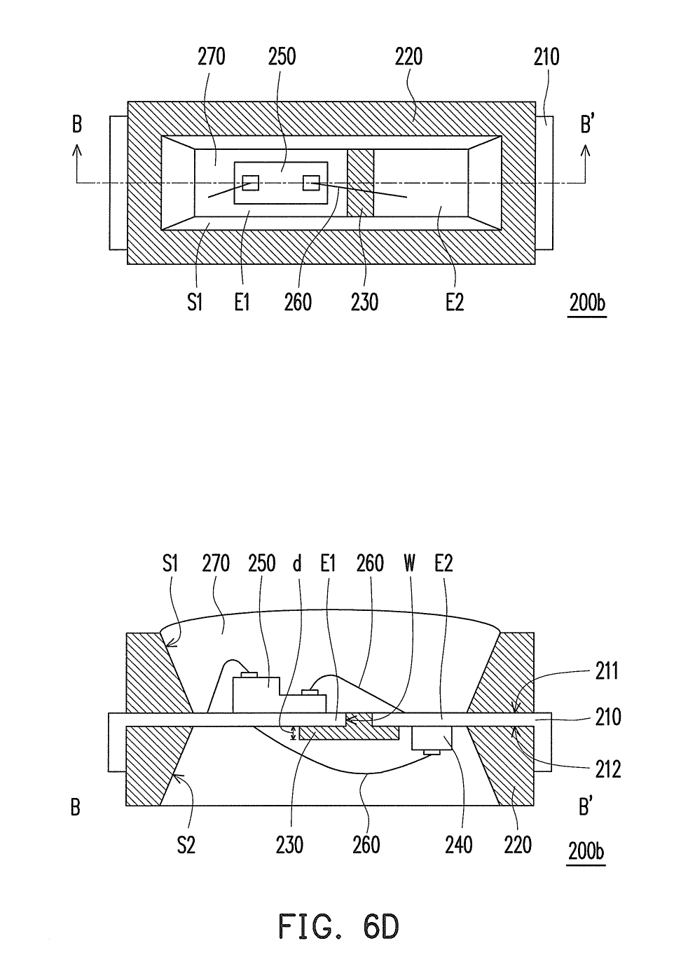

A fabrication method of the LED package 200 is described as followings. Specifically, the fabrication method of the LED package 200b shown in FIG. 3A and FIG. 3B is described as followings. FIGS. 6A-6D are schematic cross-sectional views illustrating a process flow for fabricating a light emitting diode package according to an embodiment of the present invention. FIGS. 6A-6D are schematic cross-sectional views (taken along line C-C′) illustrating a process flow for fabricating a light emitting diode package according to an embodiment of the present invention.

First, a carrier 210 having a first surface 211 and a second surface 212 opposite to the first surface 211 is provided. The carrier 210 includes a first electrode E1 and a second electrode E2, wherein a gap W is between the first electrode E1 and the second electrode E2. In the present embodiment, the carrier 210 is a leadframe fabricated by punching process or etching process. The leadframe used for carrying the LED chip 250 includes two leads (i.e. the first electrode E1 and the second electrode E2).

Referring to FIG. 3C and FIG. 6B, a package housing 220 bonded with the carrier 210 is then formed, wherein the package housing 220 has a first aperture S1 and a second aperture S2, the first surface 211 of the carrier 210 is exposed by the first aperture S1 while the second surface 212 of the carrier 210 is exposed by the second aperture S2. In addition, the strength enhancement structure 230 is formed and filled in the gap W. Specifically, as shown in FIG. 3C, the package housing 220 and the strength enhancement structure 230 can be formed simultaneously by using the first mold M1 and the second mold M2 having the groove G The package housing 220 and the strength enhancement structure 230 may be formed sequentially. In other words, the strength enhancement structure 230 is formed before or after the package housing 220 is farmed. In addition, the method of forming the package housing 220 bonded with the carrier 210 includes mold injection process or cast molding process. The material of the package housing includes plastic, metal, or metal oxide, for example.

Referring to FIG. 6C, the ESD protector 240 is disposed on the carrier 210 exposed by the second aperture S2, wherein the ESD protector 240 is electrically connected to the carrier 210. The ESD protector 240 may be disposed on and electrically connected with the carrier 210 through surface mount technology (SMT). For example, silver paste can be used in the above-mentioned surface mount technology. In another embodiment, the protector 240 may be disposed on and electrically connected with the carrier 210 through flip-chip bonding technology. In still another embodiment, the protector 240 may be disposed on and electrically connected with the carrier 210 through bonding wires 260 (i.e. wire bonding technology).

Referring to FIG. 6D, the LED chip 250 is then disposed on the carrier 210 exposed by the first aperture S1, wherein the LED chip 250 is electrically connected to the carrier 210. Similarly, the LED chip 250 is disposed on and electrically connected with the carrier 210 through flip-chip bonding technology or wire bonding technology.

Referring to FIG. 6D, after the LED chip 250 and the carrier 210 are electrically connected, an encapsulant 270 is formed to encapsulate the LED chip 250 and the carrier 210 exposed by the first aperture S1. The material of the encapsulant 270 may be silicon resin or other suitable optical materials. In addition, the encapsulant 270 may be a phosphor doped encapsulant (not shown) capable of being excited and emitting light with different colors.

During the fabrication of the LED package 200, trimming process and forming process are usually performed. The trimming process is used to cingulate the semi-finished products formed on the carrier 210. The forming process is used to bend the carrier 210 exposed outside the package housing 220 and the encapsulant 270 to form outer leads such that the LED package 200 is electrically connected to other electronic devices through the outer leads thereof. After performing the trimming process and the forming process, the LED package 200 may be used in different applications such as lamps, display panels, and so on.

In the above-mentioned method, design of the first aperture S1, the second aperture S2 and the strength enhancement structure 230 may be modified by modifying the first mold M1 and the second mold M2. Therefore, the fabrication process of the LED package 200 is simplified and the production cost is reduced. In addition, the damaged issue of the bonding wires 260 can be avoided by formation of the first aperture S1 and the second aperture S2 such that yield rate can be effectively enhanced.

In summary, the LED package and the fabricating method thereof as provided in the present application have at least the following advantages:

Amount of the material required for fabricating the package housing and the fabrication cost is reduced due to the formation of the first aperture and the second aperture. In addition, the damaged issue of the bonding wires can be avoided by the first aperture and the second aperture such that yield rate of the LED package can be effectively enhanced. Deformation of the carrier resulted from bonding stress is not occurred easily when the ESD protector and the LED chip are bonded thereto, since the strength enhancement structure provides the carrier sufficient strength. The strength enhancement structure and the apertures can be formed by properly modifying the molds and fabrication of the strength enhancement structure and the apertures is compatible with current process. The fabricating process is simple and cost-effective.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A light emitting diode (LED) package, comprising:
a carrier having a first surface and a second surface opposite to the first surface, the first surface including a first electrode and a second electrode, a gap being between the first electrode and the second electrode;
a package housing disposed on the carrier, wherein the package housing has a first aperture and a second aperture, the first surface is exposed by the first aperture while the second surface is exposed by the second aperture;
a strength enhancement structure disposed on the carrier and filled at least parts of the gap;
an electro-static discharge (ESD) protector disposed on the carrier and located within the second aperture, wherein the ESD protector is electrically connected to the carrier; and
an LED chip disposed on the carrier and located within the first aperture, wherein the LED chip is electrically connected to the carrier.

2. The LED package as claimed in claim 1, wherein the strength enhancement structure is disposed on the second surface of the carrier.

3. The LED package as claimed in claim 1, wherein the strength enhancement structure and the package housing are formed integrally.

4. The LED package as claimed in claim 1, wherein a thickness of the strength enhancement structure is greater than or equal to 0.25 micrometer.

5. The LED package as claimed in claim 1, further comprising at least one bonding wire, wherein the ESD protector is electrically connected with the carrier via the bonding wire.

6. The LED package as claimed in claim 1, further comprising a plurality of bumps, wherein the ESD protector is electrically connected with the carrier via the bumps.

7. The LED package as claimed in claim 1, wherein the ESD protector comprises a zener diode chip, a red light LED chip, a SMD type zener diode package, a SMD type red light LED package, a capacitor, a variable resistor or a surge absorber.

8. The LED package as claimed in claim 1, wherein the carrier is a leadframe.

9. The LED package as claimed in claim 1, further comprising at least one bonding wire, wherein the LED chip is electrically connected with the carrier via the bonding wire.

10. The LED package as claimed in claim 1, further comprising a plurality of bumps, wherein the LED chip is electrically connected with the carrier via the bumps.

11. The LED package of claim 1, further comprising an encapsulant, wherein the encapsulant encapsulates the LED chip and parts of the carrier exposed by the first aperture.

12. The LED package of claim 1, further comprising a phosphor doped encapsulant, wherein the phosphor doped encapsulant encapsulates the LED chip and parts of the carrier exposed by the first aperture.

13. The LED package as claimed in claim 1, wherein a material of the package housing comprises plastic, metal, or metal oxide.

14. A fabricating method of an LED package, comprising:
providing a carrier having a first surface and a second surface opposite to the first surface, wherein the carrier includes a first electrode and a second electrode, a gap is between the first electrode and the second electrode;
forming a package housing bonded with the carrier, wherein the package housing has a first aperture and a second aperture, the first surface is exposed by the first aperture while the second surface is exposed by the second aperture;
forming a strength enhancement structure on the carrier to fill at least parts of the gap;
installing an ESD protector on the carrier exposed by the second aperture and electrically connecting the ESD protector to the carrier; and
installing an LED chip on the carrier exposed by the first aperture and electrically connecting the LED chip to the carrier.

15. The fabricating method of an LED package as claimed in claim 14, wherein the strength enhancement structure is installed on the second surface of the carrier.

16. The fabricating method of an LED package as claimed in claim 14, wherein the strength enhancement structure and the package housing are formed integrally.

17. The fabricating method of an LED package as claimed in claim 14, wherein a thickness of the strength enhancement structure is greater than or equal to 0.25 micrometer.

18. The fabricating method of an LED package as claimed in claim 14, wherein the ESD protector is disposed on and electrically connected with the carrier through surface mount technology (SMT).

19. The fabricating method of an LED package as claimed in claim 14, wherein the ESD protector is disposed on and electrically connected with the carrier through flip-chip bonding technology.

20. The fabricating method of an LED package as claimed in claim 14, wherein the ESD protector is disposed on and electrically connected with the carrier through wire bonding technology.

21. The fabricating method of an LED package as claimed in claim 14, wherein the LED chip is disposed on and electrically connected with the carrier through flip-chip bonding technology.

22. The fabricating method of an LED package as claimed in claim 14, wherein the LED chip is electrically connected to the carrier through wire bonding technology.

23. The fabricating method of an LED package as claimed in claim 14, further comprising: forming an encapsulant after the LED chip and the carrier are electrically connected, wherein the encapsulant encapsulates the LED chip and parts of the carrier exposed by the first aperture.

24. The fabricating method of an LED package as claimed in claim 14, further comprising: forming a phosphor doped encapsulant after the LED chip and the carrier are electrically connected, wherein the phosphor doped encapsulant encapsulates the LED chip and parts of the carrier exposed by the first aperture.

25. The fabricating method of an LED package as claimed in claim 14, a method of forming the package housing bonded with the carrier includes mold injection process or cast molding process.
